(19) United States
(12) Patent Application Publication
(10) Pub. No.: US 2009/0243062 A1
(43) Pub. Date: Oct. 1, 2009

(54) IC TAG AND MANUFACTURING METHOD OF THE SAME

(75) Inventors: Shuichi TAKEUCHI, Kawasaki (JP); Kenji KOBAE, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/404,682

(22) Filed: Mar. 16, 2009

(30) Foreign Application Priority Data
Mar. 25, 2008 (JP) 2008-77279

(51) Int. Cl. H01L 23/48; H01L 23/02; H01L 21/50

(52) U.S. Cl. 257/678; 257/737; 438/118; 438/121; 257/E21.499; 257/E23.01; 257/E23.18

(57) ABSTRACT

An IC tag comprises a substrate on which a wiring pattern is formed, an IC chip which is bonded and mounted to the substrate by bringing a bump into press-contact with the wiring pattern, a repulsive member that is arranged on the surface opposite to the surface of the substrate on which surface the IC chip is mounted, and that is made of a material having higher rigidity than the substrate, and an exterior package member which is configured to cover the substrate, the IC chip, and the repulsive member.

### CROSS-REFERENCE TO RELATED APPLICATIONS

This application is based upon and claims the benefit of priority from the prior Japanese Patent Application No. 2008-77279 filed on Mar. 25, 2008, the entire contents of which are incorporated herein by reference.

### FIELD

An IC tag has a function to perform reading and writing of information from and to an electronic apparatus, and is used for various applications, such as article management, by utilizing this function. The IC tag includes a transmission and reception antenna used to perform transmission and reception of information to and from the electronic apparatus by wireless communication and an IC chip configured to store and control the information.

FIG. 1 shows a configuration of an IC chip mounting portion of an IC tag. An IC tag 20 is formed in such a manner that an IC chip 8 is mounted on a substrate 6 on which a wiring pattern 5 is formed, and all the members including the substrate 6 and the IC chip 8 are sealed by an exterior package member 10 made of urethane resin, and the like. The wiring pattern 5 formed on the substrate 6 is formed as an antenna pattern, and the IC chip 8 is connected to the end portion of the antenna pattern. The IC chip 8 and the antenna pattern are sealed so as to be enclosed by the exterior package member 10. The exterior package member 10 protects the IC chip 8 and the substrate 6 including the antenna pattern, and also retains the shape of the IC tag 20.

### SUMMARY

An IC tag comprises a substrate on which a wiring pattern is formed, an IC chip which is bonded and mounted to the substrate by bringing a bump into press-contact with the wiring pattern, a repulsive member that is arranged on the surface opposite to the surface of the substrate on which surface the IC chip is mounted, and that is made of a material having higher rigidity than the substrate, and an exterior package member which is configured to cover the substrate, the IC chip, and the repulsive member.

### BRIEF DESCRIPTION OF THE DRAWINGS

FIG. 1 is a sectional view showing a conventional configuration of an IC tag;

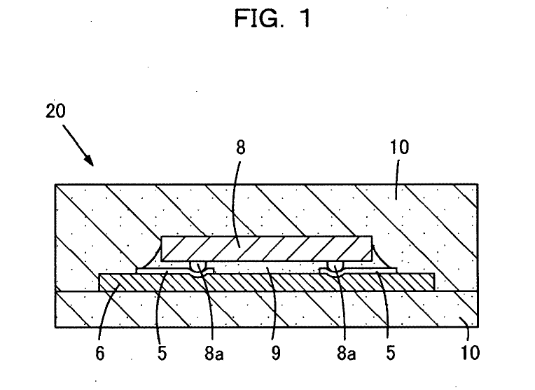

FIG. 2 is a sectional view showing an exemplary configuration of an IC tag;

FIG. 3 is an enlarged sectional view showing a bonding portion between a bump and a wiring pattern;

FIG. 4 is an illustration showing a state where an adhesive is supplied onto a substrate;

FIG. 5 is an illustration showing a process of bonding an IC chip to a substrate;

FIG. 6 is an illustration showing a process of integrating a stacked body with the adhesive;

FIG. 7 is an illustration showing a process of sealing with an exterior package member; and

FIG. 8 is a sectional view showing another configuration of the IC tag.

### DETAILED DESCRIPTION OF THE EMBODIMENTS

In the following, there will be described in detail an embodiment of an IC tag disclosed here and a manufacturing method of the IC tag with reference to accompanying drawings.

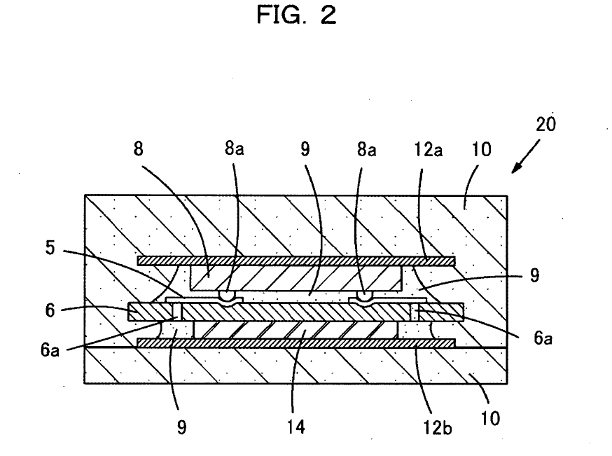

FIG. 2 is a sectional view showing a configuration of an embodiment.

An IC tag 20 according to the present embodiment fundamentally has a configuration in which a wiring pattern 5 formed on a substrate 6 is electrically connected to an IC chip 8 by bringing a bump 8a of the IC chip 8 into press-contact with the wiring pattern 5 by adhesive force and curing shrinkage force of an adhesive 9. In the present embodiment, PET is used as the substrate 6, and the wiring pattern 5, which is made of aluminum so as to serve as an antenna pattern, is formed on the substrate 6. The bump 8a of the IC chip 8, which is a gold bump or the like, is brought into press-contact with the end portion of the wiring pattern 5.

In the IC tag 20 according to the present embodiment, a pair of reinforced plates 12a and 12b are arranged so as to sandwich the substrate 6 and the IC chip 8 in the thickness direction, and a repulsive member 14 is inserted between the reinforced plate 12b and the substrate 6.

The reinforced plates 12a and 12b are formed slightly larger than the plane size of the IC chip 8. The size of the repulsive member 14 is set approximately equal to the plane size of the IC chip 8, that is, is set so that the portion at which the bump 8a and the wiring pattern 5 are brought into contact with each other is included in the plane area of the repulsive member 14.

Through holes 6a penetrating the substrate 6 in the thickness direction are provided to enable the reinforced plates 12a and 12b, the IC chip 8, the substrate 6, and the repulsive member 14 to be integrally bonded with the adhesive 9. The through holes 6a are to supply the adhesive 9 to the side opposite to the side of the substrate 6 on which side the IC chip 8 is arranged. Therefore, the through holes 6a are formed outside the plane area on which the repulsive member 14 is arranged. The through holes 6a are able to supply the adhesive 9 between the substrate 6 and the reinforced plate 12b. Thus, the number and arrangement position of the through holes 6a are not limited in particular.

The IC tag 20 has the arrangement in which respective members are sandwiched between the pair of reinforced plates 12a and 12b, and is formed in a state in which the whole bonded body integrated by the adhesive 9 is sealed and kept in shape by an exterior package member 10.

With this configuration, the IC chip 8 and the substrate 6 are pinched and supported by the reinforced plates 12a and 12b in the thickness direction. The reinforced plates 12a and 12b act to effectively apply the pinching force (compressive force) between the IC chip 8 and the substrate 6, so as to maintain the shape of the IC tag 20. The repulsive member 14 also acts to maintain the shape of the IC tag 20.

In the present embodiment, PET is used as the material of the substrate 6, and the wiring pattern 5 formed on the substrate 6 is made of aluminum. Therefore, when the pinching force is made to act between the IC chip 8 and the substrate 6, the contact portion between the bump 8a and the wiring pattern 5 is in a deflected form (recessed form). The connecting portion between the bump 8a and the wiring pattern 5 is formed only by the contact between the bump 8a and the wiring pattern 5. Thus, when the IC tag 20 is bent or when the temperature of the outside environment is changed, the press-contact force between the bump 8a and the wiring pattern 5 may be changed.

The IC tag 20 according to the present embodiment is configured such that the IC chip 8 and the substrate 6 are firmly pinched between the reinforced plates 12a and 12b to pinch the substrate 6 via the repulsive member 14. Thereby, the press-contact force between the bump 8a and the wiring pattern 5 is increased as compared with the case where the reinforced plates 12a and 12b and the repulsive member 14 are not used. That is, the repulsive force of the repulsive member 14 is made to act on the contact portion between the bump 8a and the wiring pattern 5 by providing the repulsive member 14 in the stacked body. Thereby, even when the IC tag 20 is deformed, or when the temperature of the outside environment is changed, sufficient press-contact force is applied to the contact portion between the bump 8a and the wiring pattern 5, so that the electrical connection between the bump 8a and the wiring pattern 5 can be secured.

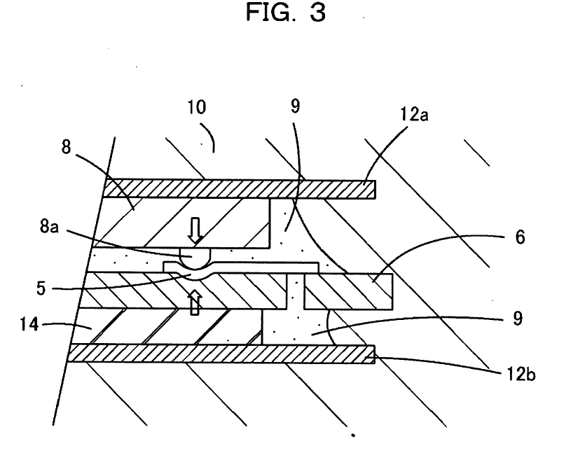

FIG. 3 is an enlarged sectional view showing the contact portion between the bump 8a and the wiring pattern 5. As described above, the IC chip 8, the substrate 6, and the repulsive member 14 are sandwiched by the reinforced plates 12a and 12b in the thickness direction and are integrally bonded by the adhesive 9. Thereby, the repulsive force of the repulsive member 14 is made to act in the direction to bring the bump 8a and the wiring pattern 5 into press-contact with each other as illustrated by the arrows in FIG. 3. The action to bring the bump 8a and the wiring pattern 5 into press-contact with each other is effected even in such a case where the IC tag 20 is deformed. Thereby, it is possible to secure the electrical connection between the bump 8a and the wiring pattern 5.

In order to secure the supporting force, a material having higher strength than the exterior package member 10 is used for the reinforced plates 12a and 12b. Further, a material having higher rigidity than the substrate 6 and the wiring pattern 5 is used for the repulsive member 14.

In the present embodiment, urethane is used for the exterior package member 10 and a glass epoxy substrate is used as the reinforced plates 12a and 12b. Further, there is used for the repulsive member 14, a material, such as polyacetal, polyamide, polycarbonate, modified polyphenylene ether, and poly butylene terephthalate, which are generally referred to as engineering plastics. These engineering plastics are materials having higher rigidity as compared with PET used for the substrate 6.

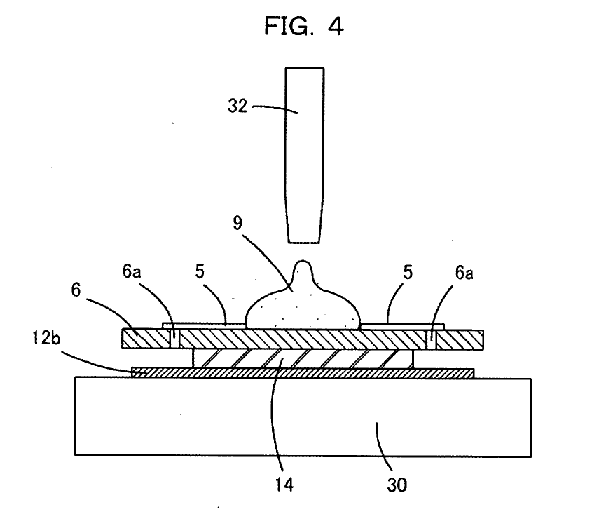

FIG. 4 to FIG. 7 show a manufacturing process of the IC tag 20 shown in FIG. 2.

FIG. 4 shows a process in which the reinforced plate 12b, the repulsive member 14, and the substrate 6 are successively arranged in superposition on a stage 30 and in which the adhesive 9 is supplied to the upper surface of the substrate 6 from a nozzle 32. As the method for arranging the reinforced plate 12b, and the like, on the stage 30, there is a method in which the respective components are successively supplied in superposition. There is also a method of supplying the reinforced plate 12b, the repulsive member 14, and the substrate 6 which are temporarily bonded in superposition beforehand. The adhesive 9 is supplied in an amount enough to fill between the IC chip 8 and the substrates 6 and to fill between the substrate 6 and the reinforced plates 12b. The through holes 6a for supplying the adhesive 9 to the side of the reinforced plate 12b are formed in the substrate 6.

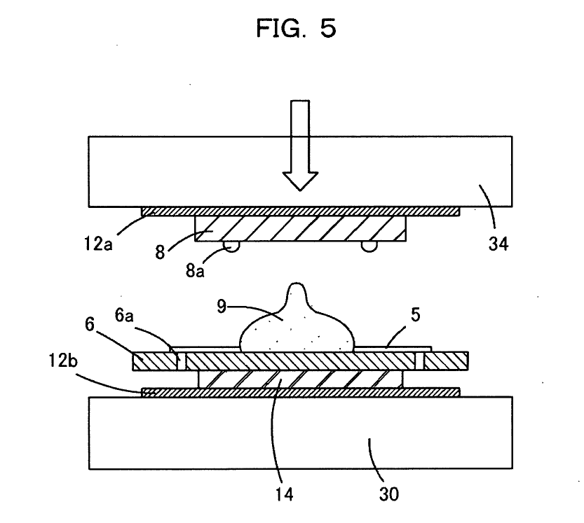

FIG. 5 shows a process of bringing the IC chip 8 into press-contact with the substrate 6 by sucking and supporting the reinforced plate 12a and the IC chip 8 with a heating and pressing head 34.

In the press-contact process, the reinforced plate 12a and the IC chip 8, which are temporarily bonded to each other, are sucked and supported by the heating and pressing head 34 so that the reinforced plate 12a and the IC chip 8 can be bonded to the substrate 6. Further, the reinforced plate 12a and the IC chip 8 can also be finally bonded to the substrate 6 in such a manner that the IC chip 8 is sucked and supported by the heating and pressing head 34 so as to be temporarily bonded to the substrate 6, and that the reinforced plate 12a is then sucked and supported by the heating and pressing head 34, so as to be pressed to the substrate 6 together with the IC chip 8.

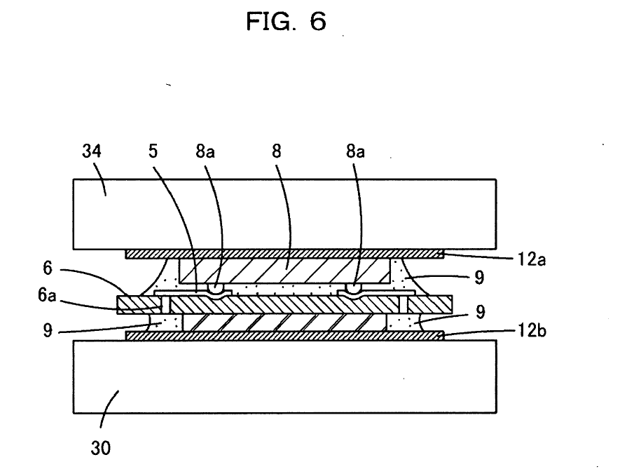

FIG. 6 shows a process in which the IC chip 8, the reinforced plate 12a, and the substrate 6 are integrally or unified bonded in such a manner that the IC chip 8 and the reinforced plate 12a are pressed to the substrate 6, while being heated, by the heating and pressing head 34 and thereby the adhesive 9 is cured. As the adhesive 9, it is possible to use, for example, an epoxy-based thermosetting adhesive.

When the IC chip 8 is pressed to the substrate 6 from above the substrate 6, the adhesive 9 is made to spread on the substrate 6, so as to seal between the IC chip 8 and the substrate 6, and a part of the adhesive 9 enters between the substrate 6 and the reinforced plate 12b from the through hole 6a. The adhesive 9 entering the side of the reinforced plate 12b fills between the substrate 6 and the reinforced plate 12b in a meniscus form on the outer periphery of the repulsive member 14.

In this state, when the reinforced plates 12a and 12b, the IC chip 8, the substrate 6, and the repulsive member 14 are heated, while being pressed, by the heating and pressing head 34, the adhesive 9 is cured, so that respective members are integrally bonded.

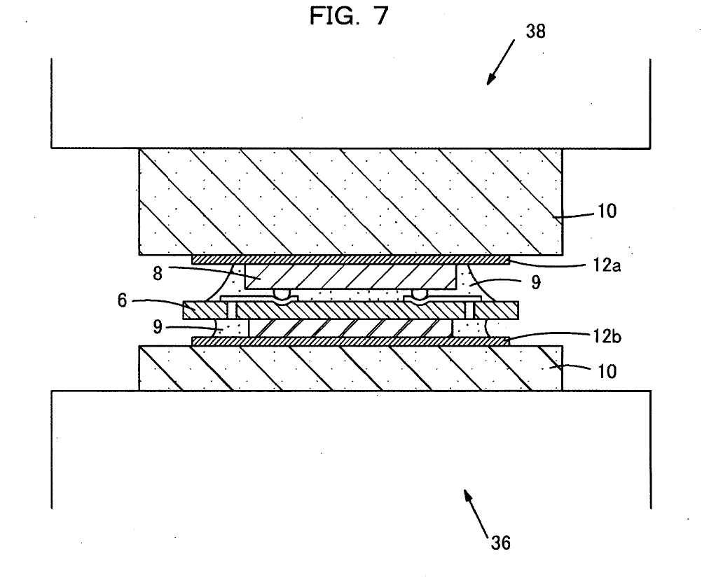

FIG. 7 shows a process in which the outer surface of the bonded body of the IC chip 8, the substrate 6, the repulsive member 14, and the reinforced plates 12a and 12b is sealed by the exterior package member 10.

In the sealing process, the bonded body is sealed in such a manner that a portion of the exterior package member 10 is arranged on a stage 36 and the bonded body is placed on this portion of the exterior package member 10, and a second portion of the exterior package member 10 is made to cover the bonded body, the exterior package member 10 is pressed, while being heated, by a heating and pressing head 38.

In the present embodiment, the bonded body is sealed in such a manner that an urethane film is arranged on the stage 36 and an urethane film is made to cover the bonded body, and that the members are heated at 150° C. to 160° C. by the heating and pressing head 38. In this way, the IC tag 20 shown in FIG. 2 is obtained.

In the manufacturing method of the IC tag according to the present embodiment, the IC tag can be easily manufactured in such a manner that the IC chip 8 and the substrate 6 are bonded to each other by the adhesive 9, and that the IC chip 8 is joined to the substrate 6 by bringing the bump 8a of the IC chip 8 into press-contact with the wiring pattern 5 of the substrate 6. Further, the method for combining the repulsive member 14 and the reinforced plates 12a and 12b, is also based on the method in which the repulsive member 14 and the reinforced plates 12a and 12b are positioned and arranged on the substrate 6. Thus, also in the method, the IC tag 20 can be easily manufactured by combining the repulsive member 14 and the reinforced plates 12a and 12b.

According to the present manufacturing method, the IC tag 20 including the repulsive member 14 and the reinforced plates 12a and 12b can be easily mass-produced, and hence can be manufactured while suppressing the manufacturing cost of the IC tag 20. Further, the IC tag 20 obtained by the present manufacturing method, is capable of improving the reliability of the electrical connection at the connecting portion between the IC chip 8 and the wiring pattern 5 by utilizing the repulsive force of the repulsive member 14, and hence can be provided as a reliable IC tag 20.

Note that in the manufacturing process of the above described embodiment, the reinforced plates 12a and 12b, the IC chip 8, the substrate 6, and the repulsive member 14 are integrally stacked with the adhesive 9 so as to be formed into the bonded body, and thereafter the bonded body is sealed by the exterior package member 10. As a method different from this process, it is also possible to adopt a method in which when the sealing is effected by the exterior package member 10, the reinforced plates 12a and 12b are arranged so as to sandwich the IC chip 8, the substrate 6, and the repulsive member 14, and in which the members are then integrated as the bonded body. Alternatively, it is also possible to adopt a method in which in the bonding process, the reinforced plate 12b is integrally bonded together with the IC chip 8, the substrate 6, and the repulsive member 14, and in which in the sealing process by the exterior package member 10, the remaining reinforced plate 12a is integrally bonded to the bonded body.

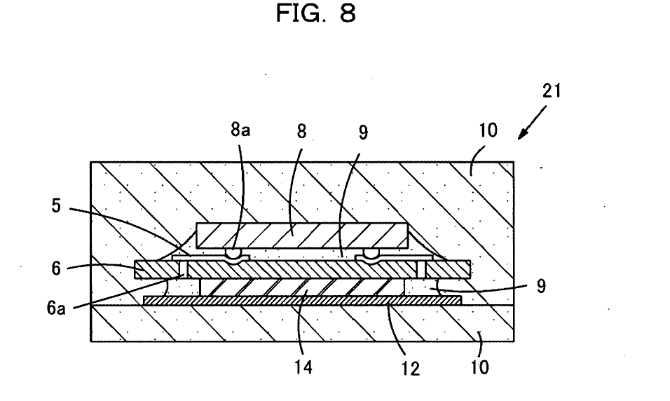

FIG. 8 shows another embodiment of an IC tag. An IC tag 21 according to the present embodiment is configured such that a reinforced plate 12 is arranged only on the side of the substrate 6 on which side the repulsive member 14 is arranged. That is, the repulsive member 14 is arranged so as to be sandwiched between the reinforced plate 12 and the substrate 6. The reinforced plate 12 and the substrate 6 are integrally joined with the adhesive 9. The IC chip 8 is simply joined to the substrate 6.

Also, in the case of the IC tag 21 according to the present embodiment which is configured such that the substrate 6 and the reinforced plate 12 are integrally joined with the adhesive 9, and that the IC chip 8 is bonded to the substrate 6, the repulsive force by the repulsive member 14 is made to act on the connecting portion between the bump 8a of the IC chip 8 and the wiring pattern 5. Thereby, it is possible to improve the reliability of the electrical connection between the IC chip 8 and the substrate 6.

In the case where the IC tag 21 of the present embodiment is formed, when the IC chip 8, the substrate 6, and the repulsive member 14 are integrally joined with the adhesive 9, it is only necessary to integrally join the members without arranging the reinforced plate on the upper surface of the IC chip 8.

According to the method of forming the IC tag 20 by arranging the reinforced plate 12 only on the side on which the repulsive member 14 is arranged, there is an advantage that the number of components can be reduced and thereby the manufacturing cost of the IC tag 20 can be reduced.

In the configuration in which the reinforced plates 12a and 12b are arranged on both sides of the stacked body in the above described embodiment, the stacked body is excellent in shape retention, and hence the action to improve the reliability of connection between the bump 8a and the wiring pattern 5 by utilizing the repulsive force by the repulsive member 14 is made more effective.

Note that each of the IC tags described in the above described embodiments is a type in which the reinforced plate is provided. When the exterior package member 10 has a certain extent of shape retention properties, it is also possible to configure the IC tag in such a manner that the repulsive member 14 is joined to the lower surface (surface opposite to the IC chip mounting surface) of the substrate 6 without the use of the reinforced plate. In this case, when the IC chip 8, the substrate 6, and the repulsive member 14 are assembled, the members may be integrally bonded by making the adhesive 9 flow around to the side on which the repulsive member 14 is arranged, or the repulsive member 14 may be simply bonded to the substrate 6. Further, when after the IC chip 8 is bonded to the substrate 6, the sealing is effected by the exterior package member 10, the repulsive member 14 can also be arranged on the surface opposite to the IC-chip mounting surface of the substrate 6, so as to be sealingly assembled together with the exterior package member 10.

According to the IC tag disclosed here, the press-contact force at the connecting portion between the bump provided on the IC chip and the wiring pattern formed on the substrate is increased by the action of the repulsive force by the repulsive member. Further, the action by the repulsive force always acts on the press-contact portion between the bump and the wiring pattern, to thereby make it possible to improve the reliability of the electrical connection between the IC chip and the substrate. Further, according to the manufacturing method of the IC tag disclosed here, it is possible to easily manufacture the IC tag including the repulsive member and the reinforced plate.

1. An IC tag comprising:
a substrate on which a wiring pattern is formed;
an IC chip bonded and mounted to the substrate by wherein a bump is contacted with the wiring pattern;
a repulsive member that is arranged on the surface opposite to the surface of the substrate on which surface the IC chip is mounted, and that is made of a material having higher rigidity than the substrate; and
an exterior package member configured to cover the substrate, the IC chip, and the repulsive member.

2. The IC tag according to claim 1, wherein the repulsive member is sized and arranged so that a portion at which the bump and the wiring pattern are brought into contact with each other is included in the plane area of the repulsive member.

3. The IC tag according to claim 1,
wherein a reinforced plate made of a material having higher rigidity than the exterior package member is arranged to sandwich the repulsive member between the reinforced plate and the substrate, and
wherein the exterior package member covers the substrate, the IC chip, the repulsive member, and the reinforced plate.

4. The IC tag according to claim 2,
wherein a reinforced plate made of a material having higher rigidity than the exterior package member is arranged to sandwich the repulsive member between the reinforced plate and the substrate, and
wherein the exterior package member covers the substrate, the IC chip, the repulsive member, and the reinforced plate.

5. The IC tag according to claim 1,
wherein a pair of reinforced plates made of a material having higher rigidity than the exterior package member are arranged to sandwich the substrate, the IC chip, and the repulsive member in the thickness direction, and
wherein the exterior package member covers the substrate, the IC chip, the repulsive member, and the reinforced plates.

6. The IC tag according to claim 2,
wherein a pair of reinforced plates made of a material having higher rigidity than the exterior package member are arranged to sandwich the substrate, the IC chip, and the repulsive member in the thickness direction, and
wherein the exterior package member covers the substrate, the IC chip, the repulsive member, and the reinforced plates.

7. The IC tag according to claim 3, wherein the substrate, the IC chip, the repulsive member, and the reinforced plate are integrally bonded with an adhesive.

8. The IC tag according to claim 4, wherein the substrate, the IC chip, the repulsive member, and the reinforced plate are integrally bonded with an adhesive.

9. The IC tag according to claim 5, wherein the substrate, the IC chip, the repulsive member, and the reinforced plate are integrally bonded with an adhesive.

10. The IC tag according to claim 6, wherein the substrate, the IC chip, the repulsive member, and the reinforced plate are integrally bonded with an adhesive.

11. The IC tag according to claim 7, wherein the substrate is provided with a through hole configured to supply the adhesive to the area outside the repulsive member and between the substrate and the reinforced plate from the surface side of the substrate on which side the IC chip is mounted.

12. A manufacturing method of an IC tag comprising:
a process of supplying an adhesive onto a substrate on which a wiring pattern is formed, in a state where the substrate, a repulsive member arranged on the surface side opposite to the surface of the substrate on which surface the wiring pattern is formed, and a reinforced plate arranged to sandwich the repulsive member between the reinforced plate and the substrate are stacked;
a process of holding an IC chip by a heating and pressing head and of bringing a pad provided on the IC chip into press-contact with the wiring pattern via the adhesive;
a process of forming a bonded body by integrally bonding the IC chip, the substrate, the repulsive member, and the reinforced plate by curing the adhesive in the state where the IC chip, the substrate, the repulsive member, and the reinforced plate are pressed by the heating and pressing head; and
a process of sealing the bonded body with an exterior package member.

13. The manufacturing method of the IC tag according to claim 12, wherein in the process of holding and press-contacting the IC chip by the heating and pressing head, the bonded body, to which the reinforced plate is integrally bonded, is formed by bringing the IC chip into press-contact with the substrate by the heating and pressing head via the reinforced plate.

14. The manufacturing method of the IC tag according to claim 12, wherein the substrate is provided with a through hole for supplying the adhesive supplied on the substrate to the side of the lower surface of the substrate, and in holding and press-contacting the IC chip by the heating and pressing head, the bonded body is formed by supplying the adhesive from the through hole to the area outside the repulsive member and between the substrate and the reinforced plate.

15. The manufacturing method of the IC tag according to claim 13, wherein the substrate is provided with a through hole for supplying the adhesive supplied on the substrate to the side of the lower surface of the substrate, and in holding and press-contacting the IC chip by the heating and pressing head, the bonded body is formed by supplying the adhesive from the through hole to the area outside the repulsive member and between the substrate and the reinforced plate.
